(19) United States
(12) Patent Application Publication
(10) Pub. No.: US 2019/0389772 A1
(43) Pub. Date: Dec. 26, 2019

(54) OXIDE SINTERED BODY

(71) Applicant: JX Nippon Mining & Metals Corporation, Tokyo (JP)

(72) Inventors: Takashi Kakeno, Ibaraki (JP); Koji Kakuta, Ibaraki (JP)

(21) Appl. No.: 15/758,813

(22) PCT Filed: Nov. 18, 2016
(86) PCT No.: PCT/JP2016/084248

§ 371 Date: Mar. 9, 2018

(30) Foreign Application Priority Data
Mar. 14, 2016 (JP) 2016-049341

(51) Int. Cl. C04B 35/457; C23C 14/34

(52) U.S. Cl. CPC C04B 35/457; C23C 14/3414; C04B 2235/3206; C04B 2235/77; C04B 2235/3286; C04B 2235/963

(57) ABSTRACT

An oxide sintered body substantially formed from indium, tin, magnesium and oxygen, wherein tin is contained at a ratio of 5 to 15% in terms of an atomic ratio of Sn/(In+Sn+Mg), magnesium is contained at a ratio of 0.1 to 2.0% in terms of an atomic ratio of Mg/(In+Sn+Mg), and remainder being indium and oxygen, and wherein a flexural strength of the oxide sintered body is 140 MPa or more when a surface roughness Ra of the oxide sintered body is 0.3 to 0.5 μm. Provided is an oxide sintered body for use as a sputtering target capable of reducing target cracking and particle generation during deposition, and capable of forming a thin film which exhibits superior amorphous stability and durability.

### BACKGROUND

The embodiment of the present invention relates to an oxide sintered body for use as a sputtering target which is suitable for forming a transparent conductive film for use in a flat panel display or the like.

An ITO (Indium Tin Oxide) film is characterized in having low resistivity, high transmissivity, and ease of microfabrication, and is being used in a broad range of fields including as a display electrode of flat panel displays because the foregoing characteristics are superior in comparison to other transparent conductive films. Today, the deposition method of an ITO film in industrial production processes is mostly so-called a sputter deposition method of sputtering an ITO sintered body as the target for its favorable uniformity and productivity to deposit an ITO film on a large area.

Meanwhile, the addition of magnesium to ITO is known as a method for improving the durability of the film, stabilizing the amorphous nature of the film, and achieving the high density of the target. For example, Patent Documents 1 to 3 disclose that a Mg-containing ITO thin film has a flat film surface with improved etching properties, and the durability of the film (moisture resistance, high temperature resistance) is also improved. Patent Documents 4 to 6 describe that a stable amorphous (non-crystalline) film can be obtained without having to add water during deposition, and that etching residue can be reduced. Patent Document 7 discloses a sintering body with improved density in which 5 to 5000 ppm of one or more elements selected from Mg and five other elements are added to ITO.

Nevertheless, when Mg is added to ITO, there are problems in that pores are easily formed on the sintered body, and that the strength of the sintered body will deteriorate. The foregoing generation of pores and deterioration of strength became a cause of particle generation and target cracking during sputtering. Meanwhile, Patent Document 8 and 9 disclose a high-strength ITO sputtering target containing 0.001 to 0.1 wt % of an oxide of at least one or more elements selected from Mg, Ca, Zr, and Hf. Documents 8 and 9 describe that the strength can be improved by adding trace amounts of an oxide of Mg or the like, but because the additive amount is so small, it is not possible to yield such an effect of stabilizing the amorphous nature of the film as described above.

Note that, in Patent Documents 8 and 9, the bending strength is measured according to JISR1601; and according to the standards of JIS, the surface roughness Ra of the test piece is 0.2 μm or less. Nevertheless, because the strength of ceramics is considerably affected by the surface roughness, for instance, even if the Ra is 0.2 μm or less, consideration must be given to the fact that the strength will differ considerably depending on whether the Ra falls slightly below 0.2 μm or whether the surface roughness is even smaller by roughly an additional digit. Moreover, it requires high cost to make the surface roughness Ra of the sintered body for use as an actual sputtering target to be 0.2 μm or less, thus it is undesirable from the industrial production perspective. In light of the above, demanded is a sintered body (target) having a high mechanical strength in a practical surface roughness range and capable of yielding effects such as improving the durability of the film and stabilizing the amorphous nature of the film.

### CITATION LIST

### Patent Documents

Patent Document 1: Japanese Patent No. 3632524
Patent Document 2: Japanese Patent No. 4075361
Patent Document 3: Japanese Patent No. 3215392
Patent Document 4: Japanese Patent No. 4885274
Patent Document 5: Japanese Patent No. 4489842
Patent Document 6: Japanese Patent No. 5237827
Patent Document 7: Japanese Patent No. 3827334
Patent Document 8: Japanese Patent No. 4855964
Patent Document 9: Japanese Patent No. 5277284

### SUMMARY

An object of the embodiment of the present invention is to provide an oxide sintered body having a high flexural strength for use as a sputtering target for forming a Mg-containing ITO film which exhibits superior amorphous stability and durability, and which is able to drastically inhibit target cracking and particle generation during sputtering.

In order to achieve the foregoing object, as a result of intense study, the present inventors discovered that it is possible to increase the flexural strength of a sintered body (sputtering target) by appropriately adjusting the composition of the sintered body and the sintering conditions, and further discovered that it is possible to consequently suppress the generation of nodules, suppress the generation of arcing and particles during sputtering, and improve the yield of the deposition process. Based on the foregoing discovery, the present inventors provide the following embodiments of the invention:

1) An oxide sintered body, which substantially formed from indium, tin, magnesium and oxygen; tin is contained at a ratio of 5 to 15% in terms of an atomic ratio of Sn/(In+Sn+Mg), magnesium is contained at a ratio of 0.1 to 2.0% in terms of an atomic ratio of Mg/(In+Sn+Mg), and remainder being indium and oxygen; and a flexural strength of the oxide sintered body is 140 MPa or more when a surface roughness Ra of the oxide sintered body is 0.3 to 0.5 μm.
2) The oxide sintered body according to 1) above, wherein the oxide sintered body has a density of 7.1 g/cm³ or more.
3) The oxide sintered body according to 1) or 2) above, wherein the number of pores having an equivalent circle diameter of 0.1 μm or more is 30 or less in an area of 80×120 μm².

The embodiment of the present invention can achieve a high flexural strength in an oxide sintered body which substantially formed from indium, tin, magnesium and oxygen by appropriately adjusting the composition of the sintered body and the sintering conditions, and it is thereby possible to yield a superior effect of enabling stable sputtering with minimal generation of particles during sputtering.

### BRIEF DESCRIPTION OF DRAWINGS

FIG. 1 is a Weibull plot showing the flexural strength of the Examples and the Comparative Examples.

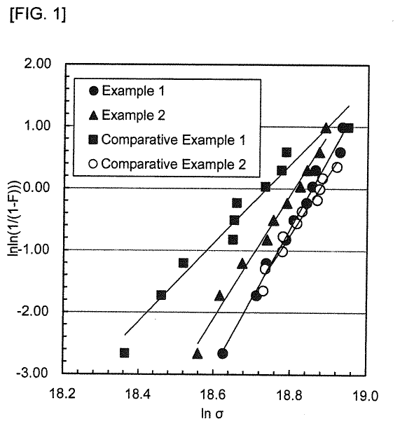

### DETAILED DESCRIPTION

The oxide sintered body of the embodiment of the present invention is substantially formed from indium, tin, magnesium and oxygen, wherein tin is contained at a ratio of 5 to 15% in terms of an atomic ratio of Sn/(In+Sn+Mg), magnesium is contained at a ratio of 0.1 to 2.0% in terms of an atomic ratio of Mg/(In+Sn+Mg), and remainder being indium and oxygen. Here, Sn represents the number of atoms of tin, In represents the number of atoms of indium, and Mg represents the number of atoms of magnesium, respectively, and the foregoing atomic ratios respectively indicate the appropriate concentration range of the atomic ratio of tin and magnesium relative to the total number of atoms of indium, tin and magnesium as all metal atoms.

A sputtering target can be prepared by processing the foregoing oxide sintered body into a predetermined diameter and thickness, and a transparent conductive film is obtained by performing sputter deposition with the sputtering target. The composition of the sputtering target and the composition of the oxide sintered body are the same, and the composition of the sputtering target and the composition of the film obtained via sputter deposition are basically the same. Moreover, the term “substantially” means that the constituent elements of the oxide sintered body are formed from only the 4 kinds, i.e. indium, tin, magnesium and oxygen, and, even if unavoidable impurities, which are contained in commonly available raw materials and cannot be entirely eliminated with a normal refining method during the production of such raw materials, are contained in an unavoidable concentration range, the term “substantially” means that the embodiment of the present invention has a concept that includes such unavoidable impurities. In other words, unavoidable impurities are included in the embodiments of the present invention.

When tin is added to indium oxide, tin functions as an n-type donor and exhibits the effect of reducing the resistivity. Normally, a commercially available ITO target has a tin concentration Sn of roughly Sn/(Sn+In)=10%. When the tin concentration is too low, the amount of electron donation will be small. On the other hand, when the tin concentration is too much, tin becomes an electron scattering impurity. In either case, the resistivity of the film obtained via sputtering will increase. Accordingly, the appropriate tin concentration range as ITO is as follows; specifically, the tin concentration Sn falls within a range of 5 to 15% in the formula of Sn/(In+Sn+Mg). Thus, the tin concentration of the embodiment of the present invention is prescribed based on the foregoing formula.

When magnesium is added to ITO, magnesium exhibits the effect of preventing the crystallization of the film, and amorphizing the film. When the magnesium concentration Mg is Mg/(In+Sn+Mg)<0.1%, there is hardly any effect of amorphizing the film, and a part of the sputtered film becomes crystallized. On the other hand, when Mg/(In+Sn+Mg)>2.0%, the annealing temperature required for crystallizing the amorphous film obtained via sputtering will become a high temperature exceeding 260° C. The costs, labor and time will be required for implementing the foregoing process, which is unsuitable in terms of productivity. In the case when the concentration of magnesium is too high, even if the film is annealed at a high temperature and crystallized, the resistivity of the obtained film will increase and result in a grave defect from the perspective of conductivity of the transparent conductive film. Accordingly, the magnesium concentration is ideally a ratio of 0.1 to 2.0% in terms of an atomic ratio of Mg/(In+Sn+Mg) as prescribed in the embodiment of the present invention. The magnesium concentration was determined in the manner described above.

What is particularly important in the embodiment of the present invention is that, in the oxide sintered body having the foregoing composition, the flexural strength is 140 MPa or more when the surface roughness Ra is 0.3 to 0.5 μm. The flexural strength was measured based on a three-point bending test in accordance with JISR1601: 2008. Specifically, an average value of ten samples having a total length of 40 mm±0.1 mm, a width of 4 mm±0.1 mm, a thickness of 3 mm±0.1 mm, a span of 30 mm+0.1 mm, and a cross head speed of 0.5 mm/min was obtained. In cases where the flexural strength is less than 140 MPa, when excessive power is input during sputtering, there is a possibility that cracks may occur in the sintered body due to the stress caused by the difference in thermal expansion between the sputtering target (sintered body) and the backing plate that is bonded with the target. Also, there are cases where arcing and particles will increase during sputtering.

The oxide sintered body of the embodiment of the present invention preferably has a density of 7.1 g/cm³ or more. The high densification of a sintered body (target) yields a superior effect of enabling not only to improve the uniformity of the sputtered film, but also significantly to reduce the generation of particles during sputtering. In the embodiment of the present invention, the sintered body density is determined by the Archimedes method; specifically, the value of the density is obtained as an average by dividing the measurement results at each place of the sample taken at five positions from one near the center and four corners of the rectangular planar target by the number of measurement points.

With the oxide sintered body of the embodiment of the present invention, the number of pores having an equivalent circle diameter of 0.1 μm or more is preferably 30 or less in an area of 80×120 μm². When the sintering is insufficient, reaction among the respective raw materials will also be insufficient; and numerous pores are generated in the sintered body. The presence of these pores will decrease the flexural strength of the sintered body and lead to increase in the variation of the flexural strength, as well as to the generation of nodules. Thus, it is desirable to reduce these pores to the extent possible. The number of pores was counted as follows; specifically, a sample having a size of roughly 1.5 cm×1.5 cm was cut out from the sintered body (center part), the cut section thereof was polished to obtain a mirror surface, and the texture of the sample was observed with an electron microscope. Subsequently, the number of pores having an equivalent circle diameter of 0.1 μm or more existing in a range of an area of 80×120 μm² at a magnification of 1000× was counted.

In general, when producing an oxide sintered body, the respective raw material powders are mixed at a predetermined ratio and then pulverized to obtain a slurry, the obtained slurry is dried with a spray drier to obtain a granulated powder, and the obtained granulated powder is thereafter molded and sintered. Nevertheless, when using “magnesium oxide” as the raw material, there is a problem in that the viscosity of the slurry would increase and make the processes of mixing, pulverization, and granulation difficult.

If the mixing of the raw material powders is insufficient, there is a possibility that warping and cracks will arise during the sintering process, as well as the density of the sintered body cannot be sufficiently increased. When a target produced from this kind of sintered body is sputtered, the generation of nodules and abnormal discharge is induced. Furthermore, the target will have a high resistivity region and a low resistivity region due to the segregation of the magnesium oxide, and the generation of abnormal discharge is further induced.

As a method of reducing the viscosity of the slurry, there is a method of adjusting the pH of the slurry. However, there is also a limit to the method, thus it is necessary to lower the solid content of the slurry in order to sufficiently lower the viscosity. Nevertheless, when a slurry having a low solid content is used, the efficiency of the granulation process will significantly deteriorate, and this will consequently deteriorate the productivity.

Meanwhile, methods of not using magnesium oxide as the raw material are also being conducted. For example, the Examples of Patent Document 1 use magnesium hydroxide as the magnesium raw material, Patent Document 2 uses indium acid magnesium or stannic acid magnesium, and Patent Document 6 uses magnesium hydroxide carbonate.

Nevertheless, magnesium hydroxide and magnesium hydroxide carbonate are extremely inadequate as the raw materials for producing a high density sintered body, because they become decomposed when heated and release water and carbon dioxide. Even in cases of using indium acid magnesium or stannic acid magnesium, it is necessary to synthesize these raw materials in advance, which will significantly reduce the productivity.

In contrast with the above methods, the embodiment of the present invention, as described later, mixes and pulverizes a tin oxide raw material and a magnesium oxide raw material to obtain a slurry, and separately pulverizes an indium oxide raw material to obtain a slurry, and subsequently mixes the obtained slurries. The method enables to obtain a high density sintered body even when magnesium oxide is used as the raw material.

The method of producing the oxide sintered body of the embodiment of the present invention is now explained in detail. Note that the method of producing the oxide sintered body of the embodiment of the present invention is not limited to the following production method, and any other production condition may be changed as appropriate to the extent that the characteristics of the oxide sintered body are not considerably changed.

Foremost, tin oxide and magnesium oxide are weighed to attain a predetermined amount and a moderate amount of deionized water is added thereto, the resulting product is sufficiently mixed using a mixer and pulverized with a bead mill to obtain a slurry. Similarly, indium oxide is weighed to attain a predetermined amount and deionized water is added thereto, and the resulting product is mixed and pulverized to obtain a slurry.

Here, the viscosity of the slurry may be adjusted by pH adjustment using acid or alkali as needed. Note that, because the raw material powders are oxides, the atmospheric gas may be the atmospheric air since there is no need to give any particular consideration for preventing the oxidation of the raw materials.

Next, the slurry obtained by mixing tin oxide and magnesium oxide and the slurry of indium oxide are mixed with a mixer and pulverized with a bead mill to obtain a slurry in which the raw material powders are uniformly mixed. Pulverization is desirably performed until the average grain size (D50) becomes 1 μm or less, preferably 0.6 μm or less.

Granulation is subsequently performed in order to improve the fluidity of the raw material powders so as to facilitate the filling process of the raw material powders during press molding. PVA (polyvinyl alcohol) which serves as a binder is mixed at a ratio of 100 to 200 cc for each kilogram of the slurry, and the resulting product is granulated under the following conditions; specifically, granulator inlet temperature of 200 to 250° C., granulator outlet temperature of 100 to 150° C., and disk rotation of 8000 to 10000 rpm.

Press molding is subsequently performed. The granulated powder is filled in a mold of a predetermined size and subject to uniaxial pressing at a surface pressure of 40 to 100 MPa for 1 to 3 minutes to obtain a molded body. When the surface pressure is less than 40 MPa, it is not possible to obtain a molded body having sufficient density. Meanwhile, there is no need for the surface pressure to exceed 100 MPa because this would require unnecessary costs and energy, and is undesirable in terms of productivity.

CIP molding is subsequently performed. The obtained molded body is doubly vacuum-packed with vinyl and subject to CIP (Cold Isostatic Pressing) at a pressure of 150 to 400 MPa for 1 to 3 minutes. When the pressure is less than 150 MPa, the effect of CIP cannot be sufficiently obtained. On the other hand, if a pressure of 400 MPa or more is applied, it is difficult to increase the density of the molded body to be a certain value or higher, and a surface pressure of 400 MPa or more is not particularly required in terms of production.

Sintering is subsequently performed. The sintering temperature is 1500 to 1600° C., the holding time is 4 to 20 hours, the rate of temperature increase is 1 to 5° C./minute, and the temperature reduction is performed via furnace cooling. When the sintering temperature is lower than 1500° C., the density of the sintered body cannot be sufficiently increased. On the other hand, when the sintering temperature exceeds 1600° C., the life of the furnace heater will deteriorate. When the holding time is shorter than 4 hours, reaction among the raw material powder will be insufficient, and the density of the sintered body cannot be sufficiently increased. In case when the sintering time exceeds 20 hours, since sufficient reaction is already achieved, this would incur costs and energy unnecessarily, and is undesirable in terms of productivity. Furthermore, when the rate of temperature increase is slower than 1° C./minute, unneeded time is required until reaching the predetermined temperature. On the other hand, when the rate of temperature increase is faster than 5° C./minute, the temperature distribution within the furnace will not increase uniformly, and cause surface irregularity.

### EXAMPLES

The embodiments of the present invention are now explained based on Examples and Comparative Examples. Note that the following Examples are merely exemplifications, and the present invention is not limited to such Examples. In other words, the present invention is limited only based on the scope of its claims, and the embodiments of the present invention also cover the other modes and modifications included therein.

### Example 1

An indium oxide powder, a tin oxide powder and a magnesium oxide powder as raw materials were weighed to attain In:Sn:Mg=90.5:9.0:0.5% in terms of an atomic ratio, and the tin oxide powder and the magnesium oxide powder were foremost mixed. Next, deionized water was added to obtain a slurry having a solid content of 30 to 50%, pH of the obtained slurry was adjusted by adding a moderate amount of ammonia, and the resulting product was thereafter mixed with a mixer and pulverized with a bead mill. The average grain size (D50) of the raw material powders in the slurry after mixing and pulverization was set to be 0.6 μm or less. Moreover, separately, deionized water was added to the indium oxide powder, which was weighed to attain a predetermined amount, to obtain a slurry, and the obtained slurry was subject to mixing and pulverization based on the same methods described above. Subsequently, the slurry obtained by mixing the tin oxide and the magnesium oxide and the slurry of the indium oxide were mixed with a mixer and pulverized with a bead mill to obtain a slurry in which the raw material powders are uniformly mixed. Next, PVA (polyvinyl alcohol) was mixed at a ratio of 125 cc for each kilogram of the slurry, and the resulting product was granulated under the following conditions; specifically, granulator inlet temperature of 220° C., granulator outlet temperature of 120° C., and disk rotation of 9000 rpm.

Next the granulated powder was filled in a mold of a predetermined size and pressed at a surface pressure of 150 to 400 MPa for 1 to 3 minutes to obtain a molded body. The obtained molded body was doubly vacuum-packed with vinyl, subject to CIP molding at 150 to 400 MPa, heated to 15600° C. at a rate of temperature increase of 3° C./minute, sintered for 15 hours at 1560° C., and thereafter cooled in a furnace. As a result of measuring the density of the sintered body obtained based on the foregoing conditions by the Archimedes method, the density was 7.11 g/cm³. Furthermore, a sintered body having a size of roughly 1.5 cm×1.5 cm was cut out from the obtained sintered body, the cut section thereof was polished to obtain a mirror surface, and the texture of the prepared sintered body was observed, and the number of pores having an equivalent circle diameter of 0.1 μm or more existing in a range of an area of 80×120 μm² observed at a magnification of 1000× was 19 pores.

Subsequently, square bar-shaped test pieces were cut out from the foregoing sintered body, the surface of the test pieces was ground in the longitudinal direction using a #80 grindstone and subsequently ground similarly in the longitudinal direction using a #400 grindstone, and 10 test pieces having a width of 4 mm, a thickness of 3 mm, and a length of 5 mm were ultimately prepared. As a result of the measuring the surface roughness of the foregoing test pieces using the surface roughness measuring device SJ-301 manufactured by Mitsutoyo Corporation, the surface roughness Ra was 0.46 μm. Moreover, other than the surface roughness Ra of the foregoing test pieces, the test pieces were subject to a flexural strength test (3-point bending test) according to the measurement method of JISR1601: 2008. As a result, the average value of the flexural strength of the 10 test pieces was 148 MPa.

### Example 2

A sintered body was fabricated under the same conditions as Example 1, except that the sintering temperature was 1540° C. The Archimedes density of the sintered body was 7.11 g/cm³. Then the texture of the prepared sintered body was observed, and the number of pores having an equivalent circle diameter of 0.1 μm or more existing in a range of an area of 80×120 μm² observed at a magnification of 1000× was 28 pores. The surface roughness Ra of the flexural strength test piece was 0.47 μm, and the average flexural strength was 141 MPa.

### Comparative Example 1

A sintered body was fabricated under the same conditions as Example 1, except that the sintering temperature was 1480° C. The Archimedes density of the sintered body was 7.09 g/cm³. Then the texture of the prepared sintered body was observed, and the number of pores having an equivalent circle diameter of 0.1 μm or more existing in a range of an area of 80×120 μm² observed at a magnification of 1000× was 42 pores. The surface roughness Ra of the flexural strength test piece was 0.45 μm, and the average flexural strength was 128 MPa.

### Comparative Example 2

As a reference example, a case where magnesium oxide is not added is described. An indium oxide powder and a tin oxide powder as raw materials were weighed to attain In:Sn=91.0:9.0 in terms of an atomic ratio, a granulated powder was prepared using a standard method, and a sintered body was fabricated under the same conditions as Example 1. The Archimedes density of the sintered body was 7.13 g/cm³. Then the texture of the prepared sintered body was observed, and the number of pores having an equivalent circle diameter of 0.1 μm or more existing in a range of an area of 80×120 μm² observed at a magnification of 1000× was 5 pores. The surface roughness Ra of the flexural strength test piece was 0.46 μm, and the average flexural strength was 153 MPa.

By way of reference, the embodiment of the present invention aims to suppress the deterioration in the density and strength of the sintered body when magnesium oxide, which is effective for the amorphization of a film, is added, but the embodiment of the present invention does not aim to imply that it is possible to improve the density and strength in comparison to an ITO sintered body that does not contain magnesium oxide.

TABLE 1

| | | | | Average |
|---|---|---|---|---|
| | | Surface | Number | Flexural |
| | Density | Roughness Ra | of Pores | Strength |
| | (g/cm3) | (μm) | (Pores) | (MPa) |
| Example 1 | 7.11 | 0.46 | 19 | 148 |
| Example 2 | 7.11 | 0.47 | 28 | 141 |
| Comparative Example 1 | 7.09 | 0.45 | 42 | 128 |
| Comparative Example 2 | 7.13 | 0.46 | 12 | 150 |

The oxide sintered body of the embodiment of the present invention is able to form a Mg-containing ITO film which exhibits superior amorphous stability and durability, and is also able to reduce the generation of cracks and particles during deposition as a result of being able to provide a sputtering target having a high flexural strength. The thin film formed by using the oxide sintered body of the embodiment of the present invention for use as a sputtering target is particularly effective as a transparent conductive film in flat panel displays and flexible panel displays.

1: An oxide sintered body comprising:
substantially formed from indium, tin, magnesium and oxygen;
tin is contained at a ratio of 5 to 15% in terms of an atomic ratio of Sn/(In+Sn+Mg), magnesium is contained at a ratio of 0.1 to 2.0% in terms of an atomic ratio of Mg/(In+Sn+Mg), and remainder being indium and oxygen; and
a flexural strength of the oxide sintered body is 140 MPa or more when a surface roughness Ra of the oxide sintered body is 0.3 to 0.5 μm.

2: The oxide sintered body according to claim 1, wherein the oxide sintered body has a density of 7.1 g/cm³ or more.

3: The oxide sintered body according to claim 2, wherein the number of pores having an equivalent circle diameter of 0.1 μm or more is 30 or less in an area of 80×120 μm².

4: The oxide sintered body according to claim 1, wherein the number of pores having an equivalent circle diameter of 0.1 μm or more is 30 or less in an area of 80×120 μm².
